(19) United States
(12) Patent Application Publication
(10) Pub. No.: US 2026/0279483 A1
(43) Pub. Date: Sep. 17, 2026

(54) RECEIVING DEVICE AND DATA JITTER SUPPRESSION METHOD THEREOF

(71) Applicant: MACRONIX International Co., Ltd., Hsinchu (TW)

(72) Inventors: Tung-Yu Li, Taoyuan City (TW); Shang-Chi Yang, Changhua County (TW); Hsuan-Chieh Lin, Kaohsiung City (TW)

(73) Assignee: MACRONIX International Co., Ltd., Hsinchu (TW)

(21) Appl. No.: 19/075,796

(22) Filed: Mar. 11, 2025

(51) Int. Cl. G11C 29/56; G11C 16/10; G11C 16/26

(52) U.S. Cl. CPC G11C 29/56012; G11C 16/10; G11C 16/26

(57) ABSTRACT

Disclosed are a receiving device and a data jitter suppression method thereof. The receiving device can be applied to a three-dimensional NAND flash memory with high capacity and high performance. The receiving device includes an input buffer and an analog feedforward equalizer (AFFE). The input buffer receives an original data signal from an external chip to generate a gained data signal. An input terminal of the AFFE is coupled to an output terminal of the input buffer to receive the gained data signal. The AFFE adjusts the inverter strength of the gained data signal to suppress data dependent jitter.

### BACKGROUND

### Technical Field

The present disclosure relates to a memory device, and particularly relates to a receiving device and a data jitter suppression method thereof.

### Description of Related Art

Memory integrated circuits including three-dimensional NAND flash memory with high capacity and high performance are under continuous development. To overcome the challenges of dimensional scaling, the NAND flash memory industry has transitioned from planar architectures to three-dimensional structures. The storage capacity of 3D vertical NAND flash memory has been steadily increasing over the past decade to meet the demands of various industries, including mobile devices and data centers. The increase in the number of stacked word-line (WL) layers has played a crucial role in achieving higher storage capacities or bit densities. This paradigm shift allows for increased storage density through vertical stacking of storage units, rather than relying solely on cell miniaturization. Charge-trap technology employs a continuous silicon nitride layer as the storage node (SN). Compared to floating gate technology, charge-trap technology is widely adopted in 3D NAND flash memory arrays due to its simpler manufacturing process and superior vertical scaling capabilities.

In memory integrated circuits, interface circuits may transmit data between internal circuits and external chips. Generally, due to the limited driving strength of Complementary Metal-Oxide-Semiconductor (CMOS) circuits, high-speed data DQ might experience data dependent jitter (DDJ). Data dependent jitter reduces eye width, thereby affecting the data valid window. The suppression of jitter in high-speed data DQ to maintain the data valid window has become one of the numerous technical issues in the field of 3D NAND flash memory.

### SUMMARY

The present disclosure provides a receiving device and a data jitter suppression method thereof to suppress data dependent jitter (DDJ) of high-speed data signals.

In an embodiment of the present disclosure, the receiving device includes an input buffer and an analog feedforward equalizer (AFFE). The input buffer receives an original data signal from an external chip to generate a gained data signal. The input terminal of the AFFE is coupled to the output terminal of the input buffer to receive the gained data signal. The AFFE adjusts the inverter strength of the gained data signal to suppress data dependent jitter.

In an embodiment of the present disclosure, the data jitter suppression method includes: receiving an original data signal from an external chip by an input buffer of the receiving device to generate a gained data signal; and adjusting the inverter strength of the gained data signal by an AFFE of the receiving device to suppress data dependent jitter.

Based on the above, the receiving device described in various embodiments of the present disclosure is configured with an AFFE to compensate for edge latency of different modes. The inverter strength of the AFFE may be set/adjusted based on actual applications. For example, when the frequency of the original data signal is high, the user may increase the inverter strength of the AFFE. Conversely, when the frequency of the original data signal is low, the user may decrease the inverter strength of the AFFE. Therefore, the receiving device may suppress data dependent jitter of the gained data signal.

To make the above-mentioned features and advantages of the present disclosure more evident and easy to understand, embodiments are specifically cited below, and detailed explanations are provided in conjunction with the accompanying drawings as follows.

### BRIEF DESCRIPTION OF THE DRAWINGS

FIG. 1 is a circuit block diagram illustrating a non-volatile memory integrated circuit according to an embodiment of the present disclosure.

FIG. 2 is a circuit block diagram illustrating a non-volatile memory integrated circuit according to an embodiment of the present disclosure.

FIG. 3 is a circuit block diagram illustrating a receiving device according to an embodiment.

FIG. 4 is a waveform diagram illustrating data signals of the receiving device according to an embodiment.

FIG. 5 is a circuit block diagram illustrating a receiving device according to an embodiment of the present disclosure.

FIG. 6 is a flow diagram illustrating a data jitter suppression method for a receiving device according to an embodiment of the present disclosure.

FIG. 7 is a waveform diagram illustrating data signals of the receiving device according to an embodiment.

FIG. 8 is a circuit block diagram illustrating an analog feedforward equalizer (AFFE) according to an embodiment of the present disclosure.

FIG. 9 is a circuit block diagram illustrating an inverter device according to an embodiment of the present disclosure.

FIG. 10 is a circuit block diagram illustrating an inverter circuit according to an embodiment of the present disclosure.

FIG. 11 is a circuit block diagram illustrating an inverter circuit according to another embodiment of the present disclosure.

FIG. 12 is a circuit block diagram illustrating an inverter device according to another embodiment of the present disclosure.

FIG. 13 is a circuit block diagram illustrating a buffer according to an embodiment of the present disclosure.

FIG. 14 is a circuit block diagram illustrating a buffer according to another embodiment of the present disclosure.

FIG. 15 is a circuit block diagram illustrating an AFFE according to another embodiment of the present disclosure.

FIG. 16 is a circuit block diagram illustrating an AFFE according to still another embodiment of the present disclosure.

### DESCRIPTION OF THE EMBODIMENTS

In the entire specification of the present disclosure (including the claims), the term “couple (or connect)” may refer to any direct or indirect connection means. For example, if the text describes that a first device is coupled (or connected) to a second device, it should be interpreted that the first device may be directly connected to the second device, or the first device may be indirectly connected to the second device through other devices or some connection means. The terms “first”, “second”, etc. mentioned in the entire specification of the present disclosure (including the claims) are used to name elements or distinguish different embodiments or ranges, and are not used to limit the upper or lower limit of the number of elements, nor to limit the order of elements. In addition, where possible, the same reference numbers for elements/structures/steps in the drawings and embodiments represent the same or similar parts. Elements/structures/steps with the same reference numbers or using the same terms in different embodiments may serve as cross-reference in corresponding descriptions.

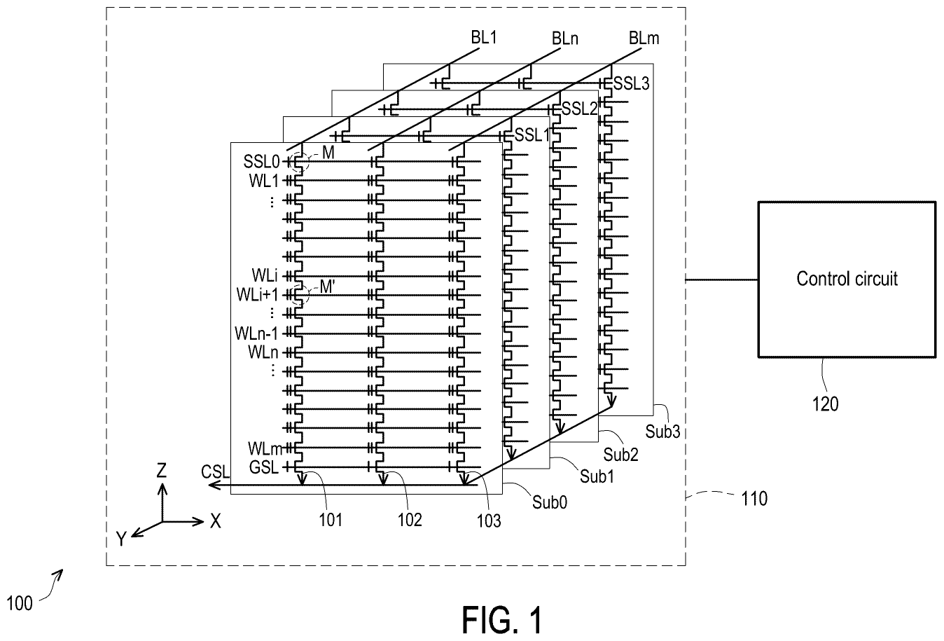

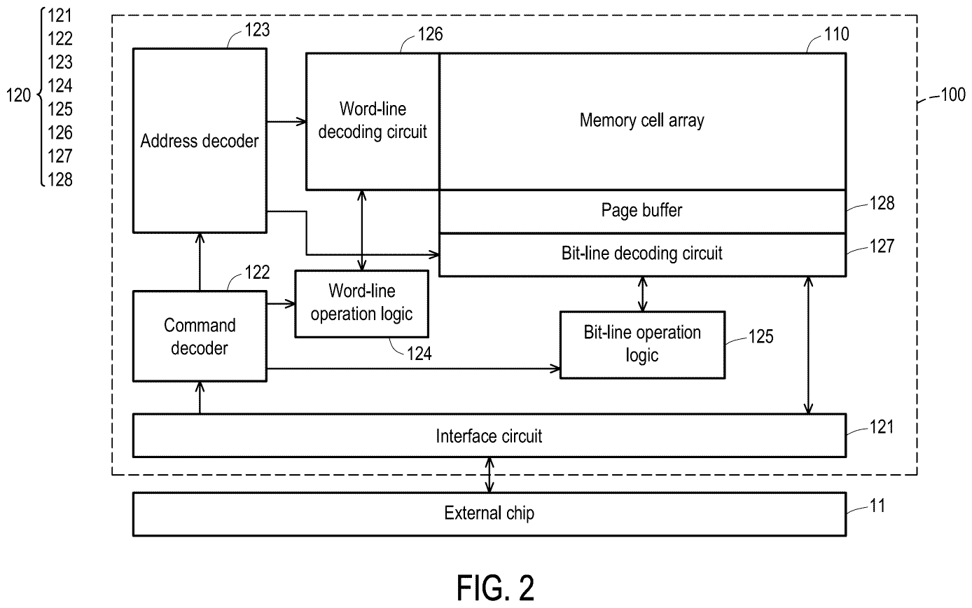

FIG. 1 is a circuit block diagram illustrating a non-volatile memory integrated circuit 100 according to an embodiment of the present disclosure. The non-volatile memory integrated circuit 100 includes a memory cell array 110 and a control circuit 120. The control circuit 120 is coupled to the memory cell array 110. The memory cell array 110 shown in FIG. 1 may serve as one of many implementation examples of the memory cell array 110 shown in FIG. 2, while the control circuit 120 shown in FIG. 2 may serve as one of many implementation examples of the control circuit 120 shown in FIG. 1. According to different designs, in some embodiments, the control circuit 120 may be implemented as a hardware circuit. In other embodiments, the control circuit 120 may be implemented as a combination of multiple forms among hardware, firmware, and software (i.e., programs).

In the form of hardware, the control circuit 120 may be implemented as a logic circuit on an integrated circuit. For example, the related functions of the control circuit 120 may be implemented in various logic blocks, modules, and circuits in one or more hardware controllers, microcontrollers, hardware processors, microprocessors, application-specific integrated circuits (ASICs), digital signal processors (DSPs), field programmable gate arrays (FPGAs), central processing units (CPUs), and/or other processing units. The related functions of the control circuit 120 may be implemented as hardware circuits, such as various logic blocks, modules, and circuits in integrated circuits, using hardware description languages (for example, Verilog HDL or VHDL) or other suitable programming languages.

In the form of software and/or firmware, the related functions of the control circuit 120 may be implemented as programming codes. For example, the control circuit 120 may be implemented using general programming languages (such as C, C++, or assembly language) or other suitable programming languages. The programming codes may be recorded/stored in a “non-transitory machine-readable storage medium”. In some embodiments, the non-transitory machine-readable storage medium may include, for example, a semiconductor memory and/or a storage device. Electronic devices (such as CPUs, hardware controllers, microcontrollers, hardware processors, or microprocessors) may read and execute the programming codes from the non-transitory machine-readable storage medium, thereby implementing the related functions of the control circuit 120.

FIG. 1 illustrates an equivalent circuit of a three-dimensional (3D) NAND flash memory integrated circuit in a three-dimensional manner. The memory cell array 110 has multiple memory cells (e.g., memory cell M'). The multiple memory cells in the memory cell array 110 shown in FIG. 1 are arranged in a 3D manner in the XYZ coordinate system. However, this does not imply that the circuit of the memory cell array 110 is limited to a 3D arrangement. In an example, the memory cell array 110 may be divided into four sub-blocks Sub0, Sub1, Sub2, and Sub3. The control circuit 120 may independently control the operation of each sub-block (e.g., sub-block Sub0).

Each memory cell string (e.g., memory cell string 101, 102, or 103) shown in FIG. 1 includes multiple memory cells (e.g., memory cell M′) connected in series along the Z direction. The memory cell array 110 includes multiple word lines (WL), such as word lines WL1, . . . , WLi, WLi+1, ..., WLn−1, WLn, . . . , WLm shown in FIG. 1. A word line (e.g., word line WLn) may correspond to a layer in the XY plane. Each of the word lines WL1 to WLm is coupled to multiple memory cells in a corresponding row of the memory cells. Multiple memory cells in each memory cell string (e.g., memory cell string 101) correspond to a word line (e.g., word line WLi+1). The memory cell M may be configured as a string select transistor coupled to a string select line (SSL, e.g., string select lines SSL0, SSL1, SSL2, and SSL3), and another memory cell may be configured as a ground select transistor coupled to a ground select line GSL. The string select transistor and the ground select transistor are located at opposite sides of each memory cell string (e.g., memory cell string 101). In this example, multiple memory cell strings (e.g., memory cell strings 101, 102, etc.) coupled to the same string select line (e.g., string select line SSL0) on the same plane (e.g., a plane defined by the X direction and Z direction) may be defined as a sub-block (e.g., sub-block Sub0).

Each of the multiple bit lines (BL) is coupled to multiple memory cells in a corresponding column of the memory cells. That is, each memory cell string (e.g., memory cell string 101, 102, or 103) is connected to a corresponding bit line (e.g., bit lines BL1, BLn, or BLm) through a corresponding string select transistor on the string select line (e.g., string select line SSL0). The memory cell strings (e.g., memory cell string 101) in the same row in different sub-blocks (e.g., sub-blocks Sub0, Sub1, etc.) along the Y direction are connected to the corresponding bit lines (e.g., bit line BL1). The string select line (e.g., string select line SSL0) may be a conductive line or a conductive layer formed above the topmost word line layer (e.g., word line WL1). Each memory cell string (e.g., memory cell string 101, 102, or 103) may be connected to the same common source line CSL through a corresponding ground select transistor on the ground select line GSL. The ground select line GSL may be a conductive line or a conductive layer formed below the bottommost word line layer (e.g., word line WLm). The common source line CSL may be a conductive layer formed above the substrate of the non-volatile memory integrated circuit 100. The string select lines (e.g., string select lines SSL0 to SSL3) in the memory cell array 110 may be on the same conductive layer but divided into independent lines. Each independent line (string select line) may independently control the operation of the corresponding sub-block (e.g., sub-blocks Sub0, Sub1, etc.) in the memory cell array 110.

In an example, under the single level cell (SLC) mode, multiple memory cells (including memory cell M′) coupled to the same word line or word line layer (e.g., word line WLn) in a sub-region (e.g., sub-region Sub0) may be defined as one page. In another example, under the triple-level cell (TLC) mode, multiple memory cells (including memory cell M′) coupled to the same word line or word line layer (e.g., word line WLn) in a sub-region (e.g., sub-region Sub0) may be defined as three pages. In the TLC mode, these three pages include a high page, a middle page, and a low page. Memory cells M′ located on the same word line (e.g., word line WLn) are applied with the same voltage. Each word line (e.g., word line WLn) may be connected to a driving circuit, such as an X-decoder (or scan driver).

In an example, one or more dummy lines or layers (not shown) may be arranged between the string select lines (e.g., string select lines SSL0 to SSL3) and the word line layer (e.g., word line WL1), as well as between the ground select line GSL and the bottommost word line layer (e.g., word line WLm). In another example, one or more dummy lines or layers (not shown) may be arranged in the middle portion of each memory cell string (e.g., memory cell string 101, 102, or 103). The non-volatile memory integrated circuit 100 further includes a control circuit 120 for implementing corresponding operations on the memory cell array 110.

FIG. 2 is a circuit block diagram illustrating a non-volatile memory integrated circuit 100 according to an embodiment of the present disclosure. Description of the non-volatile memory integrated circuit 100 shown in FIG. 2 may be derived from the related explanation of FIG. 1. An external chip 11 sends commands to and exchanges data with the non-volatile memory integrated circuit 100. Based on the control of the external chip 11 (e.g., a memory controller), the non-volatile memory integrated circuit 100 shown in FIG. 2 provides data access functionality to the external chip 11. In the embodiment shown in FIG. 2, the control circuit 120 includes an interface circuit 121, a command decoder 122, an address decoder 123, a word-line operation logic 124, a bit-line operation logic 125, a word-line decoding circuit 126, a bit-line decoding circuit 127, and a page buffer 128.

The command decoder 122 receives commands (e.g., programming command, read mode command, write mode command, etc.) from the external chip 11 through the interface circuit 121. After receiving a command, the command decoder 122 decodes this command to perform corresponding operations. For example, the command decoder 122 transmits the array address to the address decoder 123 based on the command decoding result. Based on the control of the command decoder 122, the word-line operation logic 124 notifies the word-line decoding circuit 126 of the word-line (WL) to be selected and the word-line to be deselected. The address decoder 123 decodes the array address and transmits the address decoding result to the word-line decoding circuit 126 and the bit-line decoding circuit 127. Based on the control of the address decoder 123 and the word-line operation logic 124, the word-line decoding circuit 126 selects the corresponding word-line of the memory cell array 110.

Based on the control of the command decoder 122, the bit-line operation logic 125 notifies the bit-line decoding circuit 127 of the bit line (BL) to be selected and the bit line to be deselected. Based on the control of the address decoder 123 and the bit-line operation logic 125, the bit-line decoding circuit 127 exchanges data with the external chip 11 through the interface circuit 121. The bit-line decoding circuit 127 selects the corresponding bit line of the memory cell array 110 based on the control of the bit-line operation logic 125. The page buffer 128 includes a sense amplifier, which is configured to sense the signal on the bit line to generate corresponding data.

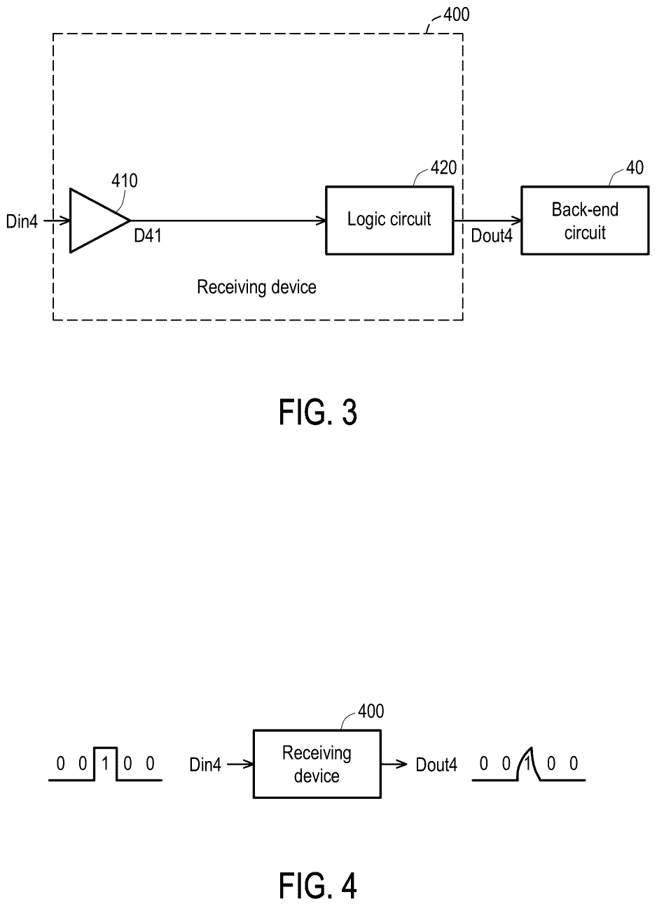

FIG. 3 illustrates a circuit block diagram of a receiving device 400 according to an embodiment. Based on actual applications, the receiving device 400 may be arranged in any functional circuit within any integrated circuit. For example, the receiving device 400 may be arranged in the interface circuit 121 of the non-volatile memory integrated circuit 100 shown in FIG. 2. The receiving device 400 receives an original data signal Din4 from an external chip (e.g., the external chip 11 shown in FIG. 2) to generate a logically processed data signal Dout4 for a back-end circuit 40. The receiving device 400 shown in FIG. 3 includes an input buffer 410 and a logic circuit 420. The input buffer 410 receives the original data signal Din4 from the external chip to generate a gained data signal D41. The input terminal of the logic circuit 420 is coupled to the output terminal of the input buffer 410 to receive the gained data signal D41. The logic circuit 420 generates the logically processed data signal Dout4 for the back-end circuit 40 based on the gained data signal D41.

FIG. 4 illustrates a waveform diagram of data signals of the receiving device 400 according to an embodiment. Generally, due to the limited driving strength of Complementary Metal-Oxide-Semiconductor (CMOS) circuits, the logically processed data signal Dout4 might experience data dependent jitter (DDJ). Data dependent jitter is likely to reduce eye width, thereby affecting the data valid window.

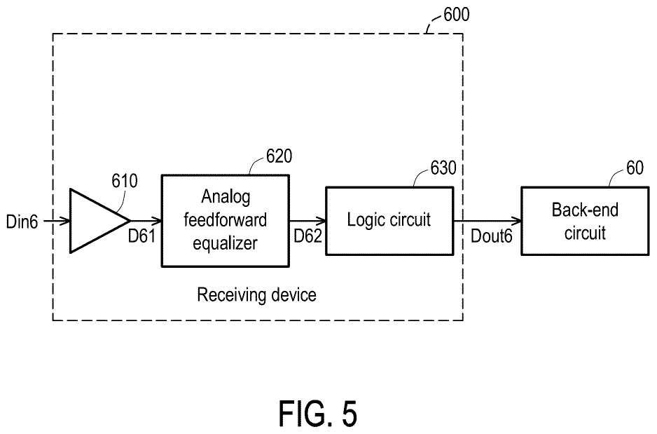

FIG. 5 illustrates a circuit block diagram of a receiving device 600 according to an embodiment of the present disclosure. Based on actual design and application, the receiving device 600 shown in FIG. 5 may be arranged in any functional circuit within any integrated circuit. For example, the receiving device 600 may be arranged in the interface circuit 121 of the non-volatile memory integrated circuit 100 shown in FIG. 2, or may be arranged in other circuits. The receiving device 600 receives an original data signal Din6 from an external chip (e.g., the external chip 11 shown in FIG. 2) to generate a logically processed data signal Dout6 for the back-end circuit 60. The receiving device 600 shown in FIG. 5 includes an input buffer 610, an analog feedforward equalizer (AFFE) 620, and a logic circuit 630. The input terminal of the AFFE 620 is coupled to the output terminal of the input buffer 610 to receive the gained data signal D61. The input terminal of the logic circuit 630 is coupled to the output terminal of the AFFE 620 to receive the delay-adjusted data signal D62. A general feedforward equalizer (FFE) focuses on equalization operations for a voltage domain, and using a general feedforward equalizer requires a clock signal. The AFFE focuses on equalization operations for a time domain. The AFFE does not require a clock signal.

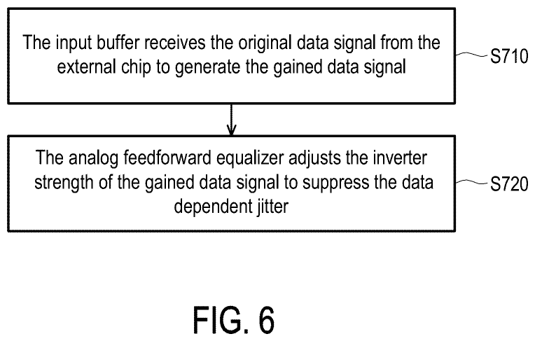

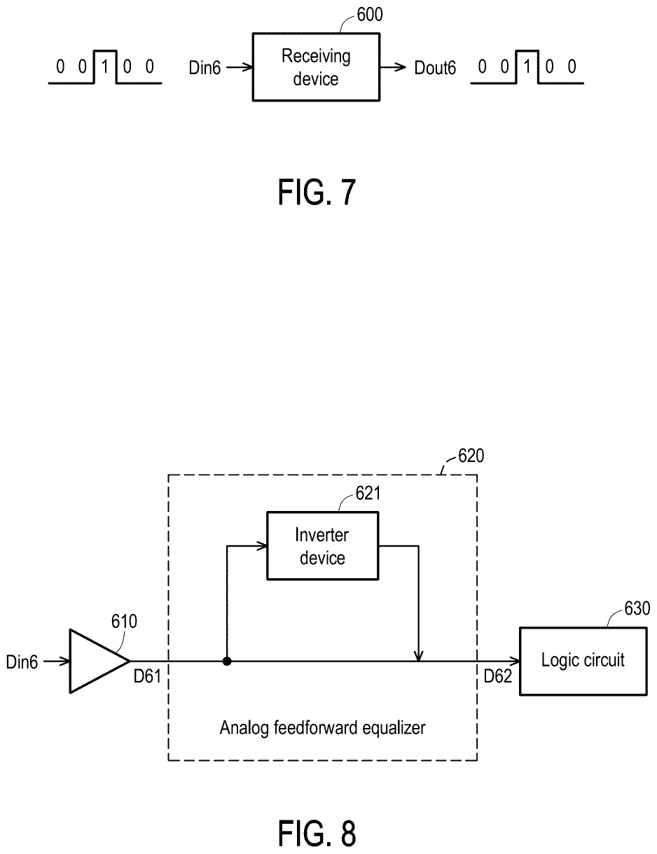

FIG. 6 illustrates a flow diagram of a data jitter suppression method for a receiving device according to an embodiment of the present disclosure. Referring to FIG. 5 and FIG. 6, in step S710, the input buffer 610 receives the original data signal Din6 from the external chip to generate the gained data signal D61. In step S720, the AFFE 620 adjusts the inverter strength of the gained data signal D61 to suppress the data dependent jitter (DDJ) of the gained data signal D61, thereby generating the delay-adjusted data signal D62. The logic circuit 630 generates the logically processed data signal Dout6 based on the delay-adjusted data signal D62, and provides the logically processed data signal Dout6 to the back-end circuit 60.

FIG. 6 illustrates a waveform diagram of data signals of the receiving device 600 according to an embodiment. The receiving device 600 is configured with the AFFE 620 to compensate for edge latency of different modes. The inverter strength of the AFFE 620 may be set/adjusted based on actual applications. For example, when the frequency of the original data signal Din6 is high, the user may increase the inverter strength of the AFFE 620. Conversely, when the frequency of the original data signal Din6 is low, the user may decrease the inverter strength of the AFFE 620. Therefore, the receiving device 600 may suppress the data dependent jitter of the logically processed data signal Dout6.

FIG. 8 illustrates a circuit block diagram of the AFFE 620 according to an embodiment of the present disclosure. The AFFE 620 shown in FIG. 8 may serve as one of many implementation examples of the AFFE 620 shown in FIG. 5. Description of the original data signal Din6, the gained data signal D61, the delay-adjusted data signal D62, the input buffer 610, the AFFE 620, and the logic circuit 630 shown in FIG. 8 may be derived from the related explanations in FIG. 5, so they will not be repeated here. In the embodiment shown in FIG. 8, the AFFE 620 includes an inverter device 621. Both the input terminal and output terminal of the inverter device 621 are coupled to the same transmission path between the output terminal of the input buffer 610 and the input terminal of the logic circuit 630, as shown in FIG. 8. The signal output from the output terminal of the inverter device 621 is an inverted signal of the gained data signal D61. It should be noted that the driving capability of the output terminal of the inverter device 621 is weaker than the driving capability of the output terminal of the input buffer 610. Therefore, the output terminal of the inverter device 621 does not change the logic state of the output terminal of the input buffer 610, but may suppress the data dependent jitter of the gained data signal D61.

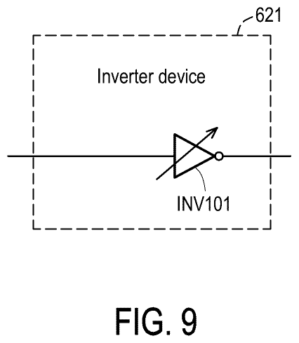

FIG. 9 illustrates a circuit block diagram of the inverter device 621 according to an embodiment of the present disclosure. The inverter device 621 shown in FIG. 9 may serve as one of many implementation examples of the inverter device 621 shown in FIG. 8. Description of the inverter device 621 shown in FIG. 9 may be derived from the related explanations in FIG. 8, so they will not be repeated here. In the embodiment shown in FIG. 9, the inverter device 621 includes an inverter circuit INV101. The input terminal of the inverter circuit INV101 is coupled to the input terminal of the inverter device 621 to receive the gained data signal D61. The output terminal of the inverter circuit INV101 is coupled to the output terminal of the inverter device 621. The driving capability of the output terminal of the inverter circuit INV101 is weaker than the driving capability of the output terminal of the input buffer 610. Therefore, the output terminal of the inverter circuit INV101 does not change the logic state of the output terminal of the input buffer 610, but may suppress the data dependent jitter of the gained data signal D61.

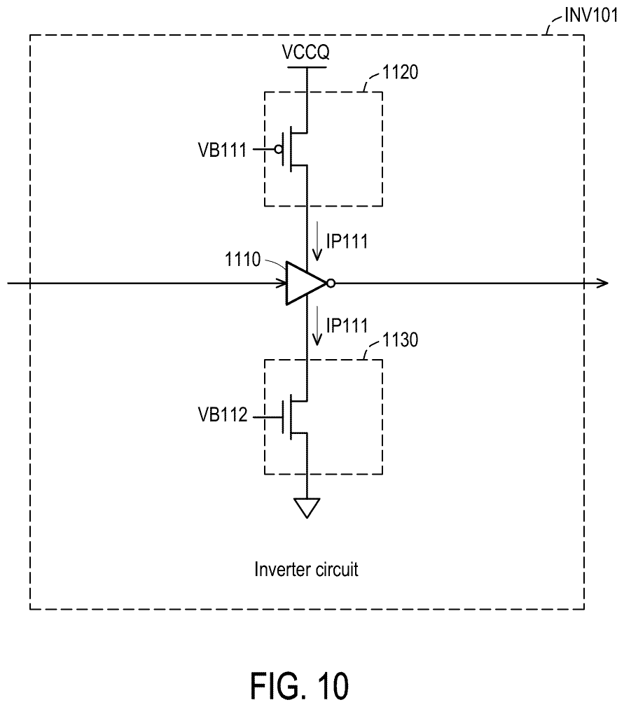

This embodiment does not limit the specific implementation method of the inverter circuit INV101. For example, FIG. 10 illustrates a circuit block diagram of the inverter circuit INV101 according to an embodiment of the present disclosure. The inverter circuit INV101 shown in FIG. 10 may serve as one of many implementation examples of the inverter circuit INV101 shown in FIG. 9. Description of the inverter circuit INV101 shown in FIG. 10 may be derived from the related explanations in FIG. 9, so they will not be repeated here. In the embodiment shown in FIG. 10, the inverter circuit INV101 includes an inverter 1110, a power current adjustment circuit 1120, and a power current adjustment circuit 1130. The input terminal of the inverter 1110 is coupled to the input terminal of the inverter circuit INV101 to receive the gained data signal D61. The output terminal of the inverter 1110 is coupled to the output terminal of the inverter circuit INV101. The driving capability of the output terminal of the inverter 1110 is weaker than the driving capability of the output terminal of the input buffer 610.

The power current adjustment circuit 1120 is coupled to the power terminal of the inverter 1110 to provide the adjusted power current IP111. The reference symbol “VCCQ” shown in FIG. 10 represents a power voltage. The power current adjustment circuit 1130 is coupled to the reference terminal of the inverter 1110 to draw the adjusted power current IP111. The power current adjustment circuits 1120 and 1130 are controlled by bias voltages VB111 and VB112. Based on the setting/adjustment of the bias voltages VB111 and VB112, the power current adjustment circuits 1120 and 1130 may adjust the power current IP111, thereby adjusting the inverter strength of the inverter 1110. For example, when the frequency of the gained data signal D61 is high, the power current adjustment circuits 1120 and 1130 adaptively reduce the power current IP111 (the inverter strength of the inverter 1110 is increased). When the frequency of the gained data signal D61 is low, the power current adjustment circuits 1120 and 1130 adaptively increase the power current IP111 (the inverter strength of the inverter 1110 is decreased).

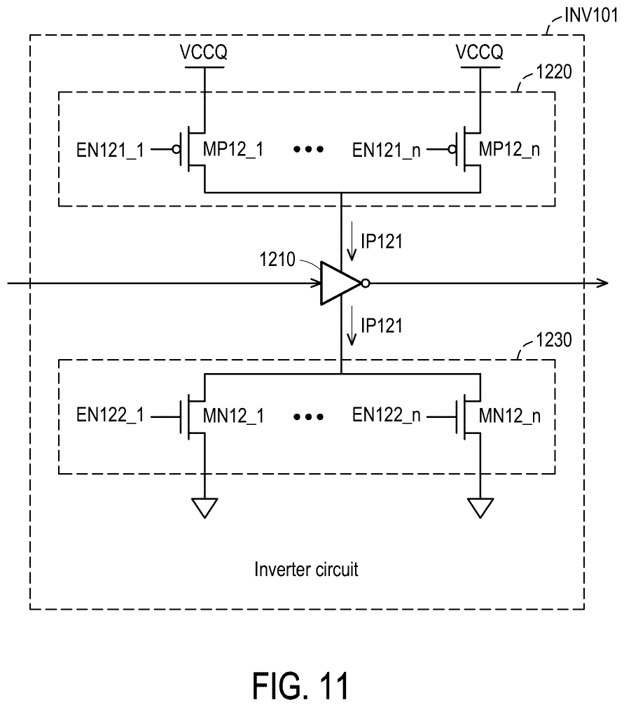

FIG. 11 illustrates a circuit block diagram of the inverter circuit INV101 according to another embodiment of the present disclosure. The inverter circuit INV101 shown in FIG. 11 may serve as one of many implementation examples of the inverter circuit INV101 shown in FIG. 9. Description of the inverter circuit INV101 shown in FIG. 11 may be derived from the related explanations in FIG. 9, so they will not be repeated here. In the embodiment shown in FIG. 11, the inverter circuit INV101 includes an inverter 1210, a power current adjustment circuit 1220, and a power current adjustment circuit 1230. The input terminal of the inverter 1210 is coupled to the input terminal of the inverter circuit INV101 to receive the gained data signal D61. The output terminal of the inverter 1210 is coupled to the output terminal of the inverter circuit INV101. The driving capability of the output terminal of the inverter 1210 is weaker than the driving capability of the output terminal of the input buffer 610.

The power current adjustment circuit 1220 is coupled to the power terminal of the inverter 1210 to provide the adjusted power current IP121. The power current adjustment circuit 1230 is coupled to the reference terminal of the inverter 1210 to draw the adjusted power current IP121. The power current adjustment circuits 1220 and 1230 are controlled by enable signals EN121_1, . . . , EN121_n and EN122_1, . . . , EN122_n. Based on the settings of the enable signals EN121_1 to EN121_n and EN122_1 to EN122_n, the power current adjustment circuits 1220 and 1230 may adjust the power current IP121, thereby adjusting the inverter strength of the inverter 1210.

In the embodiment shown in FIG. 11, the power current adjustment circuit 1220 includes n transistors MN12_1, . . . , MN12_n, while the power current adjustment circuit 1230 includes n transistors MP12_1, . . . , MP12_n. The source terminals of transistors MP12_1 to MP12_n receive the power voltage VCCQ. The drain terminals of transistors MP12_1 to MP12_n are coupled to the power terminal of the inverter 1210. The reference terminal of the inverter 1210 is coupled to the drain terminals of transistors MN12_1 to MN12_n. The source terminals of transistors MN12_1 to MN12_n receive a reference voltage (for example, ground voltage or other fixed voltage). The enable signals EN121_1 to EN121_n may turn on (or cut off) some or all of the transistors MP12_1 to MP12_n, while the enable signals EN122_1 to EN122_n may turn on (or cut off) some or all of the transistors MN12_1 to MN12_n. Therefore, based on the settings of enable signals EN121_1 to EN121_n and EN122_1 to EN122_n, the power current adjustment circuits 1220 and 1230 may adjust the power current IP121, thereby adjusting the inverter strength of the inverter 1210.

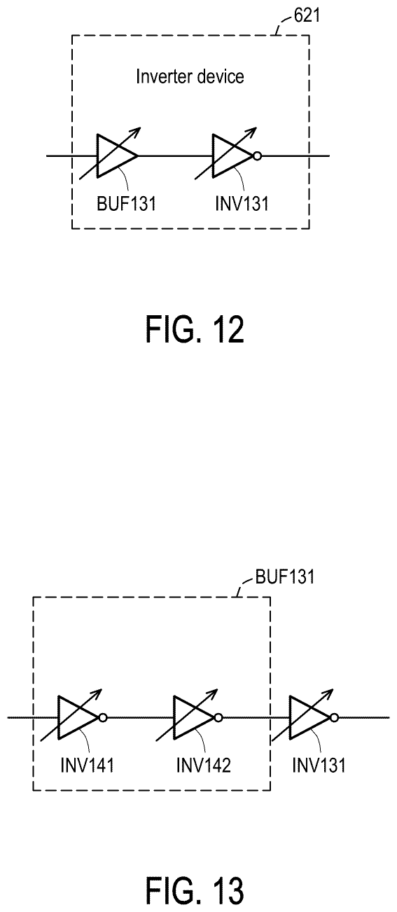

FIG. 12 illustrates a circuit block diagram of the inverter device 621 according to another embodiment of the disclosure. The inverter device 621 shown in FIG. 12 may serve as one of many implementation examples of the inverter device 621 shown in FIG. 8. Description of the inverter device 621 shown in FIG. 12 may be derived from the related explanation of FIG. 8, so it will not be repeated here. In the embodiment shown in FIG. 12, the inverter device 621 includes a buffer BUF131 and an inverter circuit INV131. The input terminal of the buffer BUF131 is coupled to the input terminal of the inverter device 621 to receive the gained data signal D61. The input terminal of the inverter circuit INV131 is coupled to the output terminal of the buffer BUF131. The output terminal of the inverter circuit INV131 is coupled to the output terminal of the inverter device 621. The driving capability of the output terminal of the inverter circuit INV131 is weaker than the driving capability of the output terminal of the input buffer 610. Therefore, the output terminal of the inverter circuit INV131 does not change the logic state of the output terminal of the input buffer 610, but may suppress the data dependent jitter of the gained data signal D61.

This embodiment does not limit the specific implementation of the buffer BUF131 and the inverter circuit INV131. For example, description of the inverter circuit INV131 shown in FIG. 12 may be derived from the related explanation of the inverter circuit INV111 shown in FIG. 10 and may be analogized accordingly.

FIG. 13 illustrates a circuit block diagram of the buffer BUF131 according to an embodiment of the disclosure. The buffer BUF131 shown in FIG. 13 may serve as one of many implementation examples of the buffer BUF131 shown in FIG. 12. In the embodiment shown in FIG. 13, the buffer BUF131 includes an inverter circuit INV141 and an inverter circuit INV142. The input terminal of the inverter circuit INV141 is coupled to the input terminal of the buffer BUF131 to receive the gained data signal D61. The input terminal of the inverter circuit INV142 is coupled to the output terminal of the inverter circuit INV141. The output terminal of the inverter circuit INV142 is coupled to the output terminal of the buffer BUF131, that is, coupled to the input terminal of the inverter circuit INV131. This embodiment does not limit the specific implementation of the inverter circuits INV141 and INV142. For example, description of either of the inverter circuits INV141 and INV142 shown in FIG. 13 may be derived from the related explanation of the inverter circuit INV111 shown in FIG. 10 and may be analogized accordingly.

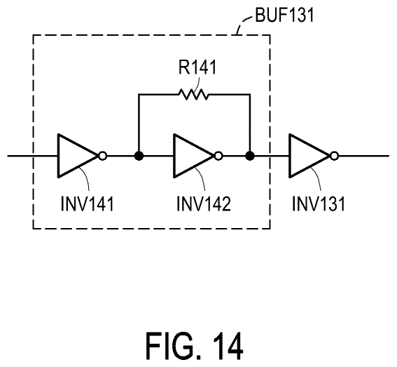

FIG. 14 illustrates a circuit block diagram of the buffer BUF131 according to another embodiment of the disclosure. The buffer BUF131 shown in FIG. 14 may serve as one of many implementation examples of the buffer BUF131 shown in FIG. 12. In the embodiment shown in FIG. 14, the buffer BUF131 includes a resistor R141, an inverter circuit INV141, and an inverter circuit INV142. Description of the inverter circuit INV131 and the inverter circuits INV141 and INV142 shown in FIG. 14 may be derived from the related explanation of FIG. 13 and may be analogized accordingly, so they will not be repeated here. When the bandwidth is insufficient, the resistor R141 may be added to the buffer BUF131. In the embodiment shown in FIG. 14, the first terminal of the resistor R141 is coupled to the input terminal of the inverter circuit INV142. The second terminal of the resistor R141 is coupled to the output terminal of the inverter circuit INV142.

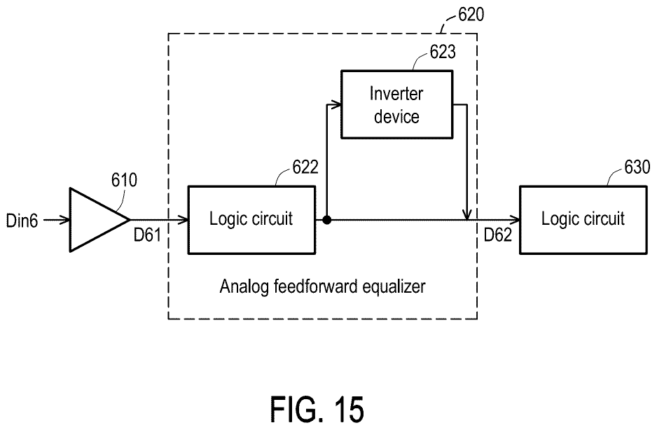

FIG. 15 illustrates a circuit block diagram of the AFFE 620 according to another embodiment of the disclosure. The AFFE 620 shown in FIG. 15 may serve as one of many implementation examples of the AFFE 620 shown in FIG. 5. Description of the original data signal Din6, the gained data signal D61, the delay-adjusted data signal D62, the input buffer 610, the AFFE 620, and the logic circuit 630 shown in FIG. 15 may be derived from the related explanation of FIG. 5, so they will not be repeated here. In the embodiment shown in FIG. 15, the AFFE 620 includes a logic circuit 622 and a inverter device 623. The input terminal of the logic circuit 622 is coupled to the output terminal of the input buffer 610 to receive the gained data signal D61. The output terminal of the logic circuit 622 provides the delay-adjusted data signal D62 to the logic circuit 630. Both the input terminal and output terminal of the inverter device 623 are coupled to the same transmission path between the output terminal of the logic circuit 622 and the input terminal of the logic circuit 630, as shown in FIG. 15. The signal output from the output terminal of the inverter device 623 is an inverted signal of the delay-adjusted data signal D61. It should be noted that the driving capability of the output terminal of the inverter device 623 is weaker than the driving capability of the output terminal of the logic circuit 622. Therefore, the output terminal of the inverter device 623 does not change the logic state of the output terminal of the logic circuit 622, but may suppress the data dependent jitter of the gained data signal D61.

This embodiment does not limit the specific implementation of the inverter device 623. For example, description of the inverter device 623 shown in FIG. 15 may be derived from the related explanation of the inverter device 621 shown in FIG. 9 and may be analogized accordingly. That is, the inverter device 623 includes an inverter circuit (the driving capability of the output terminal of this inverter circuit is weaker than the driving capability of the output terminal of the logic circuit 622), wherein the input terminal of this inverter circuit is coupled to the input terminal of the inverter device 623, and the output terminal of this inverter circuit is coupled to the output terminal of the inverter device 623. In another example, description of the inverter device 623 shown in FIG. 15 may be derived from the related explanation of the inverter device 621 shown in FIG. 12 and may be analogized accordingly.

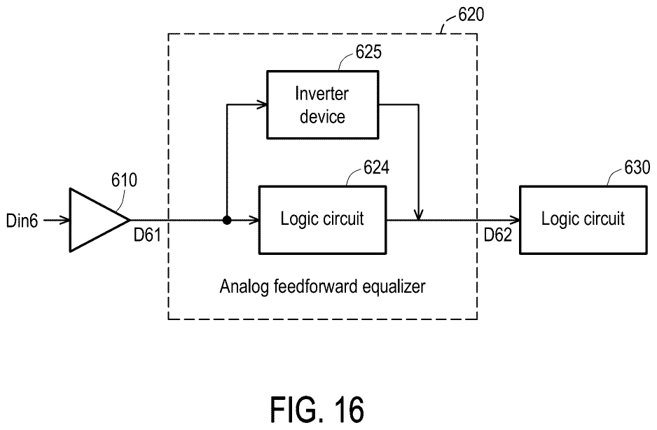

FIG. 16 is a circuit block diagram illustrating an AFFE 620 according to yet another embodiment of the disclosure. The AFFE 620 shown in FIG. 16 may serve as one of many implementation examples of the AFFE 620 shown in FIG. 5. Description of the original data signal Din6, the gained data signal D61, the delay-adjusted data signal D62, the input buffer 610, the AFFE 620, and the logic circuit 630 shown in FIG. 16 may be derived from the related explanation of FIG. 5, so they will not be repeated here. In the embodiment shown in FIG. 16, the AFFE 620 includes a logic circuit 624 and a inverter device 625. The input terminal of the logic circuit 624 is coupled to the output terminal of the input buffer 610 to receive the gained data signal D61. The output terminal of the logic circuit 622 provides the delay-adjusted data signal D62 to the logic circuit 630.

The input terminal of the inverter device 625 is coupled to the input terminal of the logic circuit 624. The output terminal of the inverter device 625 is coupled to the output terminal of the logic circuit 624. The signal output from the output terminal of the inverter device 623 is an inverted signal of the delay-adjusted data signal D61. It should be noted that the driving capability of the output terminal of the inverter device 625 is weaker than the driving capability of the output terminal of the logic circuit 624. Therefore, the output terminal of the inverter device 625 may not change the logic state of the output terminal of the logic circuit 624, but may suppress the data dependent jitter of the gained data signal D61.

This embodiment does not limit the specific implementation of the inverter device 625. For example, description of the inverter device 625 shown in FIG. 16 may be derived from the related explanation of the inverter device 621 shown in FIG. 9 and may be analogized accordingly. That is, the inverter device 625 includes an inverter circuit (the driving capability of the output terminal of this inverter circuit is weaker than the driving capability of the output terminal of the logic circuit 624), wherein the input terminal of this inverter circuit is coupled to the input terminal of the inverter device 625, and the output terminal of this inverter circuit is coupled to the output terminal of the inverter device 625. In another example, description of the inverter device 625 shown in FIG. 16 may be derived from the related explanation of the inverter device 621 shown in FIG. 12 and may be analogized accordingly.

In summary, the receiving device 600 is configured with an AFFE 620 to compensate for edge latency of different modes. The inverter strength of the AFFE 620 may be set/adjusted based on actual applications. For example, when the frequency of the original data signal Din 6 is high, the user may increase the inverter strength of the AFFE 620. Conversely, when the frequency of the original data signal Din6 is low, the user may decrease the inverter strength of the AFFE 620. Therefore, the receiving device 600 may suppress data dependent jitter of the gained data signal D61.

Although the present disclosure has been disclosed by the above embodiments, it is not intended to limit the disclosure. Any person skilled in the art may make minor modifications and refinements without departing from the spirit and scope of this disclosure. Therefore, the scope sought to be protected by the present disclosure should be defined by the appended claims.

What is claimed is:

1. A receiving device comprising:
an input buffer receiving an original data signal from an external chip to generate a gained data signal; and
an analog feedforward equalizer, wherein an input terminal of the analog feedforward equalizer is coupled to an output terminal of the input buffer to receive the gained data signal, and the analog feedforward equalizer adjusts an inverter strength of the gained data signal to suppress data dependent jitter.

2. The receiving device according to claim 1 further comprising:
a first logic circuit, wherein an input terminal of the first logic circuit is coupled to an output terminal of the analog feedforward equalizer to receive a delay-adjusted data signal, and the first logic circuit provides a logically processed data signal to a back-end circuit of the receiving device.

3. The receiving device according to claim 2, wherein the analog feedforward equalizer comprises:
an inverter device, wherein an input terminal and an output terminal of the inverter device are both coupled to a same transmission path between the output terminal of the input buffer and the input terminal of the first logic circuit, a signal output from the output terminal of the inverter device is an inverted signal of the gained data signal, and a driving capability of the output terminal of the inverter device is weaker than a driving capability of the output terminal of the input buffer.

4. The receiving device according to claim 3, wherein the inverter device comprises:
an inverter circuit, wherein an input terminal of the inverter circuit is coupled to the input terminal of the inverter device, an output terminal of the inverter circuit is coupled to the output terminal of the inverter device, and a driving capability of the output terminal of the inverter circuit is weaker than the driving capability of the output terminal of the input buffer.

5. The receiving device according to claim 4, wherein the inverter circuit comprises:
an inverter, wherein an input terminal of the inverter is coupled to the input terminal of the inverter circuit, an output terminal of the inverter is coupled to the output terminal of the inverter circuit, and a driving capability of the output terminal of the inverter is weaker than the driving capability of the output terminal of the input buffer;
a first power current adjustment circuit coupled to a power terminal of the inverter to provide a first adjusted power current; and
a second power current adjustment circuit coupled to a reference terminal of the inverter to draw a second adjusted power current.

6. The receiving device according to claim 3, wherein the inverter device comprises:
a buffer, wherein an input terminal of the buffer is coupled to the input terminal of the inverter device; and
a first inverter circuit, wherein an input terminal of the first inverter circuit is coupled to an output terminal of the buffer, an output terminal of the first inverter circuit is coupled to the output terminal of the inverter device, and a driving capability of the output terminal of the first inverter circuit is weaker than the driving capability of the output terminal of the input buffer.

7. The receiving device according to claim 6, wherein the buffer comprises:
a second inverter circuit, wherein an input terminal of the second inverter circuit is coupled to the input terminal of the buffer; and
a third inverter circuit, wherein an input terminal of the third inverter circuit is coupled to an output terminal of the second inverter circuit, and an output terminal of the third inverter circuit is coupled to the output terminal of the buffer.

8. The receiving device according to claim 7, wherein the buffer further comprises:
a resistor, wherein a first terminal of the resistor is coupled to the input terminal of the third inverter circuit, and a second terminal of the resistor is coupled to the output terminal of the third inverter circuit.

9. The receiving device according to claim 2, wherein the analog feedforward equalizer comprises:
a second logic circuit, wherein an input terminal of the second logic circuit is coupled to the output terminal of the input buffer to receive the gained data signal, and an output terminal of the second logic circuit provides the delay-adjusted data signal to the first logic circuit; and
an inverter device, wherein an input terminal and an output terminal of the inverter device are both coupled to a same transmission path between the output terminal of the second logic circuit and the input terminal of the first logic circuit, a signal output from the output terminal of the inverter device is an inverted signal of the delay-adjusted data signal, and a driving capability of the output terminal of the inverter device is weaker than a driving capability of the output terminal of the second logic circuit.

10. The receiving device according to claim 9, wherein the inverter device comprises:
an inverter circuit, wherein an input terminal of the inverter circuit is coupled to the input terminal of the inverter device, an output terminal of the inverter circuit is coupled to the output terminal of the inverter device, and a driving capability of the output terminal of the inverter circuit is weaker than the driving capability of the output terminal of the second logic circuit.

11. The receiving device according to claim 2, wherein the analog feedforward equalizer comprises:
a second logic circuit, wherein an input terminal of the second logic circuit is coupled to the output terminal of the input buffer to receive the gained data signal, and an output terminal of the second logic circuit provides the delay-adjusted data signal to the first logic circuit; and
an inverter device, wherein an input terminal of the inverter device is coupled to the input terminal of the second logic circuit, an output terminal of the inverter device is coupled to the output terminal of the second logic circuit, and a driving capability of the output terminal of the inverter device is weaker than a driving capability of the output terminal of the second logic circuit.

12. The receiving device according to claim 11, wherein the inverter device comprises:
an inverter circuit, wherein an input terminal of the inverter circuit is coupled to the input terminal of the inverter device, an output terminal of the inverter circuit is coupled to the output terminal of the inverter device, and a driving capability of the output terminal of the inverter circuit is weaker than the driving capability of the output terminal of the second logic circuit.

13. A data jitter suppression method for a receiving device, comprising:
receiving an original data signal from an external chip by an input buffer of the receiving device to generate a gained data signal; and
adjusting an inverter strength of the gained data signal by an analog feedforward equalizer of the receiving device to suppress data dependent jitter, wherein an input terminal of the analog feedforward equalizer is coupled to an output terminal of the input buffer to receive the gained data signal.

14. The data jitter suppression method according to claim 13, further comprising:
providing a logically processed data signal to a back-end circuit of the receiving device by a first logic circuit of the receiving device, wherein an input terminal of the first logic circuit is coupled to an output terminal of the analog feedforward equalizer to receive a delay-adjusted data signal.

15. The data jitter suppression method according to claim 14, wherein the analog feedforward equalizer comprises an inverter device, an input terminal and an output terminal of the inverter device are both coupled to a same transmission path between the output terminal of the input buffer and the input terminal of the first logic circuit, a signal output from the output terminal of the inverter device is an inverted signal of the gained data signal, and a driving capability of the output terminal of the inverter device is weaker than a driving capability of the output terminal of the input buffer.

16. The data jitter suppression method according to claim 15, wherein the inverter device comprises an inverter circuit, an input terminal of the inverter circuit is coupled to the input terminal of the inverter device, an output terminal of the inverter circuit is coupled to the output terminal of the inverter device, and a driving capability of the output terminal of the inverter circuit is weaker than the driving capability of the output terminal of the input buffer.

17. The data jitter suppression method according to claim 15, wherein the inverter device comprises a buffer and a inverter circuit, an input terminal of the buffer is coupled to the input terminal of the inverter device, an input terminal of the inverter circuit is coupled to an output terminal of the buffer, an output terminal of the inverter circuit is coupled to the output terminal of the inverter device, and a driving capability of the output terminal of the inverter circuit is weaker than the driving capability of the output terminal of the input buffer.

18. The data jitter suppression method according to claim 14, further comprising:
providing the delay-adjusted data signal to the first logic circuit by an output terminal of a second logic circuit of the analog feedforward equalizer, wherein an input terminal of the second logic circuit is coupled to the output terminal of the input buffer to receive the gained data signal, an input terminal and an output terminal of an inverter device of the analog feedforward equalizer are both coupled to a same transmission path between the output terminal of the second logic circuit and the input terminal of the first logic circuit, a signal output from the output terminal of the inverter device is an inverted signal of the delay-adjusted data signal, and a driving capability of the output terminal of the inverter device is weaker than a driving capability of the output terminal of the second logic circuit.

19. The data jitter suppression method according to claim 14, further comprising:
providing the delay-adjusted data signal to the first logic circuit by an output terminal of a second logic circuit of the analog feedforward equalizer, wherein an input terminal of the second logic circuit is coupled to the output terminal of the input buffer to receive the gained data signal, an input terminal of an inverter device of the analog feedforward equalizer is coupled to the input terminal of the second logic circuit, an output terminal of the inverter device is coupled to the output terminal of the second logic circuit, and a driving capability of the output terminal of the inverter device is weaker than a driving capability of the output terminal of the second logic circuit.
